(19) United States
(12) Patent Application Publication
(10) Pub. No.: US 2025/0275268 A1
(43) Pub. Date: Aug. 28, 2025

(54) IMAGE SENSOR AND IMAGE SENSOR MANUFACTURING METHOD

(71) Applicant: OMNIVISION TECHNOLOGIES, INC., Santa Clara, CA (US)

(72) Inventor: Ryuji TOMITA, Kanagawa (JP)

(21) Appl. No.: 18/801,310

(22) Filed: Aug. 12, 2024

(30) Foreign Application Priority Data
Feb. 27, 2024 (JP) 2024-027164

(51) Int. Cl. H01L 27/146

(52) U.S. Cl. CPC H10F 39/802; H10F 39/014; H10F 39/18; H10F 39/811

(57) ABSTRACT

An image sensor includes a photodiode, a floating diffusion, a ground region, a transfer channel, and an insulation film. The photodiode is formed in a lower layer of a substrate. The floating diffusion and the ground region are formed in or on top of an upper layer of the substrate. The transfer channel has a lower end connected to the photodiode. An upper end of the transfer channel is connected to the floating diffusion. The insulation film blocks at least a shortest path between the transfer channel and the ground region

### CROSS-REFERENCE(S) TO RELATED APPLICATION(S)

This application claims priority to Japanese Patent Application No. 2024-027164 filed on Feb. 27, 2024, which is incorporated herein by reference in its entirety including the specification, claims, drawings, and abstract

### TECHNICAL FIELD

The present specification discloses an image sensor and its manufacturing method.

### BACKGROUND

For example, U.S. Pat. No. 8,658,956 B, JP 2008-300446 A, and US 2005/0121708 A each disclose an image sensor in which a photodiode, a transfer gate, and a floating diffusion are arranged in a horizontal plane. Further, US 2023/0197757 A discloses an image sensor in which a photodiode, a transfer gate, and a floating diffusion are vertically arranged.

FIGS. 30 and 31 show cross-sectional views of a backside illuminated image sensor according to conventional art. FIG. 30 shows a horizontal cross section taken along line Z-Z in FIG. 31. FIG. 31 shows a vertical cross section taken along line Y-Y in FIG. 30.

For example, in a backside illuminated image sensor, a photodiode PD is formed in a lower layer as shown in FIG. 31. Further, as shown in FIG. 30, functional regions such as a floating diffusion FD and a ground region GND are formed in an upper layer. With pixel size reductions, inter-regional distances (i.e., distances between elements) such as those shown as distances D100 and D102 in FIG. 30 become smaller. As a result, when a transfer gate (TX) is applying a voltage, that is, during a process of transferring charges from the photodiode PD to the floating diffusion FD, there occurs a risk that part of the charges may leak to the functional regions such as the ground region GND and the transfer gate TX or to an electrode.

In view of the above, the present specification discloses an image sensor capable of suppressing leakage current in a charge transfer path from a photodiode to a floating diffusion.

### SUMMARY

An image sensor disclosed herein includes a substrate having a multilayer structure. The image sensor comprises a photodiode, a floating diffusion, a ground region, a transfer channel, and an insulation film. The photodiode is formed in a lower layer of the substrate. The floating diffusion and the ground region are formed in or on top of an upper layer of the substrate. The transfer channel has a lower end connected to the photodiode. An upper end of the transfer channel is connected to the floating diffusion. The insulation film blocks at least a shortest path between the transfer channel and the ground region.

According to the above configuration, the shortest path between the transfer channel and the ground region is blocked by the insulation film. With this feature, it is possible to suppress leakage current from the transfer channel to the ground region.

In the above configuration, a trench may be formed in the image sensor. The trench has a frame shape that surrounds the transfer channel. A gate insulation film is formed at least at a side surface of the trench, and the transfer channel is enclosed in a tubular manner by the gate insulation film.

By having the transfer channel enclosed in a tubular manner by the gate insulation film, leakage current can be suppressed not only in the shortest path between the transfer channel and the ground region but also in paths that bypass the shortest path.

In the above configuration, the gate insulation film may be formed at a bottom surface of the trench in addition to at the side surface. In that case, a transfer gate is formed on top of the gate insulation film. The depth of the trench exceeds the thickness of the transfer gate, and the transfer gate is formed at the bottom part of the trench.

According to the above configuration, the floating diffusion and the transfer gate are isolated in the thickness direction.

In the above configuration, the floating diffusion may be an epitaxial layer.

According to the above configuration, since the floating diffusion is formed on top of the substrate, an isolation distance in the thickness direction from the transfer gate can be ensured.

In the above configuration, the transfer channel may have a lower impurity concentration than the floating diffusion and the photodiode.

According to the above configuration, it is possible to avoid electrical conduction between the floating diffusion and the photodiode at the time when no voltage is applied by the transfer gate. Further, by forming the transfer channel inside the substrate by doping impurities, a charge transfer path can be provided.

In the above configuration, the floating diffusion may be an embedded layer. In that case, a region of the transfer gate that is relatively close to the floating diffusion has a smaller layer thickness than a region of the transfer gate that is relatively far from the floating diffusion.

According to the above configuration, the floating diffusion is formed inside the substrate. Meanwhile, the region of the transfer gate that is relatively close to the floating diffusion is formed to have a small thickness. Accordingly, the floating diffusion and the transfer gate can be isolated from each other in the thickness direction.

In the above configuration, the floating diffusion may be an embedded layer. In that case, a contact hole extends deeper than the floating diffusion and reaches the transfer gate.

According to the above configuration, the floating diffusion and the transfer gate can be isolated from each other in the thickness direction.

In the above configuration, the image sensor may comprise a transfer gate and an element-isolating insulation film. The transfer gate is located adjacent to the transfer channel in the surface direction. The element-isolating insulation film surrounds the photodiode. In this structure, the transfer channel is enclosed in a tubular manner by the gate insulation film and the element-isolating insulation film.

According to the above configuration, the transfer channel is enclosed in a tubular manner by the gate insulation film and the element-isolating insulation film. With this feature, it is possible to suppress leakage current between the transfer channel and other parts such as an electrode or a functional region.

In the above configuration, the image sensor may comprise a photoelectric conversion unit. The photoelectric conversion unit includes the photodiode, the transfer gate, the gate insulation film, and the element-isolating insulation film. Further, the image sensor includes a plurality of such photoelectric conversion units, a single such transfer channel, and a single such floating diffusion. The single transfer channel and the single floating diffusion are surrounded by the plurality of photoelectric conversion units.

According to the above configuration, the transfer channel is enclosed in a tubular manner by the gate insulation films and the element-isolating insulation films formed in the plurality of photoelectric conversion units. With this feature, it is possible to suppress leakage current between the transfer channel and other parts such as an electrode or a functional region.

In the above configuration, the ground region may be an epitaxial layer.

The present specification further discloses an image sensor manufacturing method. The image sensor includes a substrate having a multilayer structure. In this manufacturing method, a photodiode is formed in a lower layer of the substrate. A transfer channel is formed such that its lower end is connected to the photodiode. A floating diffusion is formed in or on top of an upper layer of the substrate so as to be connected to an upper end of the transfer channel. Further, a ground region is formed in or on top of the upper layer. In addition, an insulation film is formed, which blocks at least a shortest path between the transfer channel and the ground region.

In the above configuration, a trench having a frame shape that surrounds the transfer channel may be formed. In that case, a gate insulation film is formed at least at a side surface of the trench, and the transfer channel is enclosed in a tubular manner by the gate insulation film.

In the above configuration, the gate insulation film may be formed at a bottom surface of the trench in addition to the side surface. Further, a transfer gate may be formed on top of the gate insulation film. In that case, the depth of the trench exceeds the thickness of the transfer gate, and the transfer gate is formed at the bottom part of the trench.

In the above configuration, the floating diffusion may be formed by epitaxial growth.

In the above configuration, the transfer channel may have a lower impurity concentration than the floating diffusion and the photodiode.

In the above configuration, the floating diffusion may be formed as an embedded layer by ion implantation. In that case, a region of the transfer gate that is relatively close to the floating diffusion has a smaller layer thickness than a region of the transfer gate that is relatively far from the floating diffusion.

In the above configuration, the floating diffusion may be formed as an embedded layer by ion implantation, and a contact hole may be formed. The contact hole extends deeper than the floating diffusion and reaches the transfer gate.

In the above configuration, a transfer gate may be formed adjacent to the transfer channel in the surface direction. Further, an element-isolating insulation film may be formed. The element-isolating insulation film surrounds the photodiode. In this structure, the entire periphery of the transfer channel is enclosed by the gate insulation film and the element-isolating insulation film.

In the above configuration, a photoelectric conversion unit may be formed in the image sensor. The photoelectric conversion unit comprises the photodiode, the transfer gate, the gate insulation film, and the element-isolating insulation film. Further, the image sensor includes a plurality of such photoelectric conversion units, a single such transfer channel, and a single such floating diffusion. The single transfer channel and the single floating diffusion are surrounded by the plurality of photoelectric conversion units.

In the above configuration, the ground region may be formed by epitaxial growth.

According to the image sensor and the image sensor manufacturing method disclosed in the present specification, leakage current can be suppressed in the charge transfer path from the photodiode to the floating diffusion.

### BRIEF DESCRIPTION OF DRAWINGS

Embodiment(s) of the present disclosure will be described based on the following figures, wherein:

FIG. 1 is a diagram showing a horizontal cross section B-B in an image sensor according to a first embodiment;

FIG. 2 is a diagram showing a vertical cross section A-A in the image sensor according to the first embodiment;

FIG. 3 is a view of the vertical cross section A-A illustrating a charge transfer process in the image sensor according to the first embodiment;

FIG. 4 is a vertical cross-sectional view showing a manufacturing process (1/9) of the image sensor according to the first embodiment;

FIG. 5 is a vertical cross-sectional view showing the manufacturing process (2/9) of the image sensor according to the first embodiment;

FIG. 6 is a vertical cross-sectional view showing the manufacturing process (3/9) of the image sensor according to the first embodiment;

FIG. 7 is a vertical cross-sectional view showing the manufacturing process (4/9) of the image sensor according to the first embodiment;

FIG. 8 is a vertical cross-sectional view showing the manufacturing process (5/9) of the image sensor according to the first embodiment;

FIG. 9 is a vertical cross-sectional view showing the manufacturing process (6/9) of the image sensor according to the first embodiment;

FIG. 10 is a vertical cross-sectional view showing the manufacturing process (7/9) of the image sensor according to the first embodiment;

FIG. 11 is a vertical cross-sectional view showing the manufacturing process (8/9) of the image sensor according to the first embodiment;

FIG. 12 is a vertical cross-sectional view showing the manufacturing process (9/9) of the image sensor according to the first embodiment;

FIG. 13 is a diagram showing a horizontal cross section D-D in an image sensor according to a second embodiment;

FIG. 14 is a diagram showing a vertical cross section C-C in the image sensor according to the second embodiment;

FIG. 15 is a vertical cross-sectional view showing a manufacturing process (1/6) of the image sensor according to the second embodiment;

FIG. 16 is a vertical cross-sectional view showing the manufacturing process (2/6) of the image sensor according to the second embodiment;

FIG. 17 is a vertical cross-sectional view showing the manufacturing process (3/6) of the image sensor according to the second embodiment;

FIG. 18 is a vertical cross-sectional view showing the manufacturing process (4/6) of the image sensor according to the second embodiment;

FIG. 19 is a vertical cross-sectional view showing the manufacturing process (5/6) of the image sensor according to the second embodiment;

FIG. 20 is a vertical cross-sectional view showing the manufacturing process (6/6) of the image sensor according to the second embodiment;

FIG. 21 is a diagram showing a horizontal cross section F-F in an image sensor according to a third embodiment;

FIG. 22 is a diagram showing a vertical cross section E-E in the image sensor according to the third embodiment;

FIG. 23 is a vertical cross-sectional view showing a manufacturing process of the image sensor according to the third embodiment;

FIG. 24 is a diagram showing a horizontal cross section H-H in an image sensor according to a fourth embodiment;

FIG. 25 is a diagram showing a vertical cross section G-G in the image sensor according to the fourth embodiment;

FIG. 26 is a diagram showing a horizontal cross section J-J in an image sensor according to a fifth embodiment;

FIG. 27 is a diagram showing a vertical cross section I-I in the image sensor according to the fifth embodiment;

FIG. 28 is a diagram showing a vertical cross section in an image sensor according to a sixth embodiment;

FIG. 29 is a diagram showing a horizontal cross section in an image sensor according to a seventh embodiment;

FIG. 30 is a diagram showing a horizontal cross section Z-Z in an image sensor according to conventional art; and

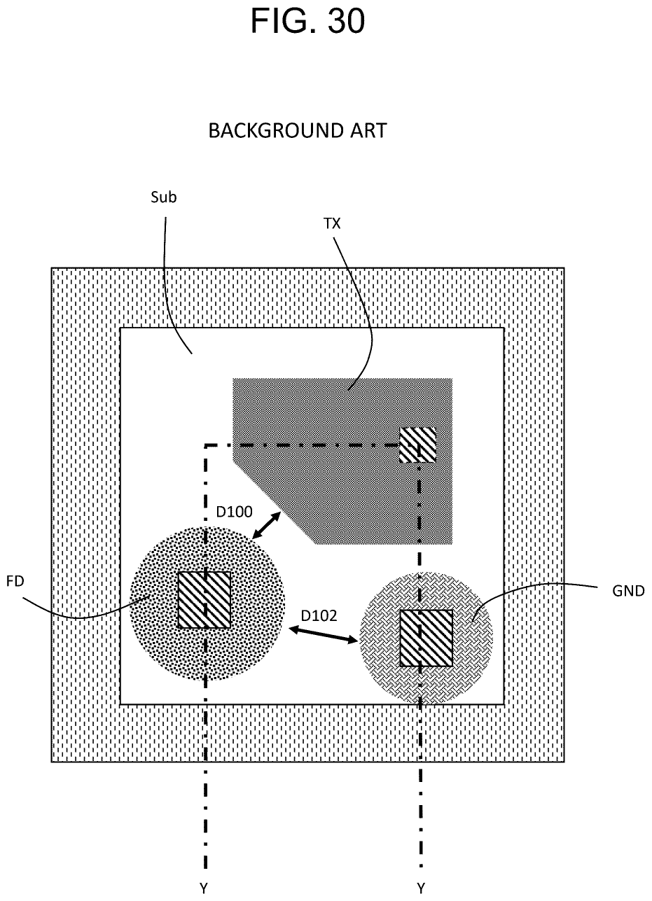

FIG. 31 is a diagram showing a vertical cross section Y-Y in the image sensor according to conventional art.

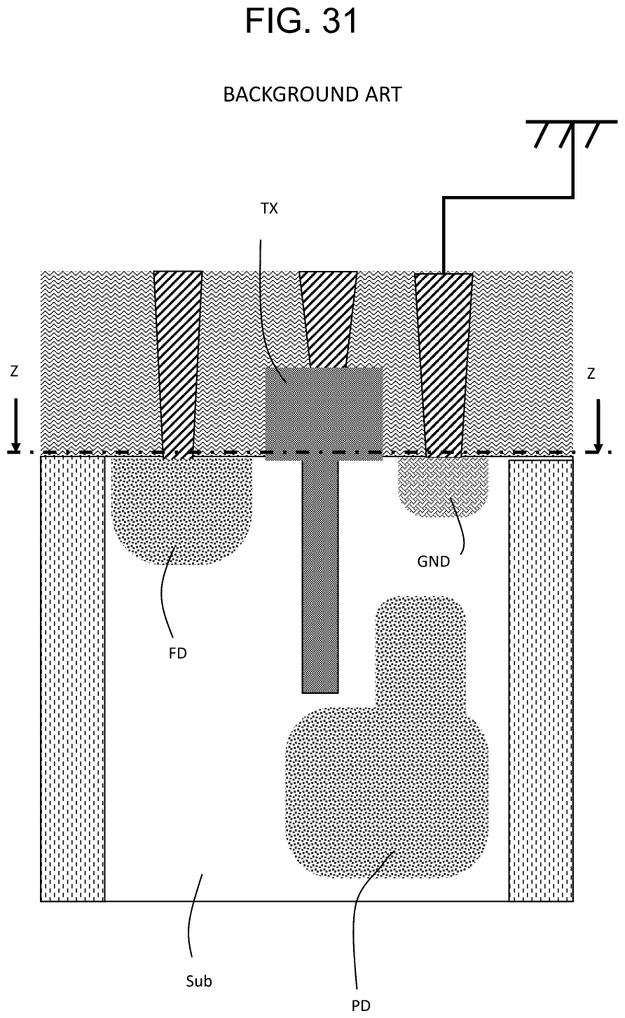

### DESCRIPTION OF EMBODIMENTS

An image sensor and its manufacturing method are described below by reference to the drawings. The shapes, materials, numbers of items, and numerical values described below are referred to simply by way of example. Those shapes and the like can be changed as appropriate in accordance with specifications of the image sensor. In the following description, identical elements in all of the drawings are assigned the same reference signs.

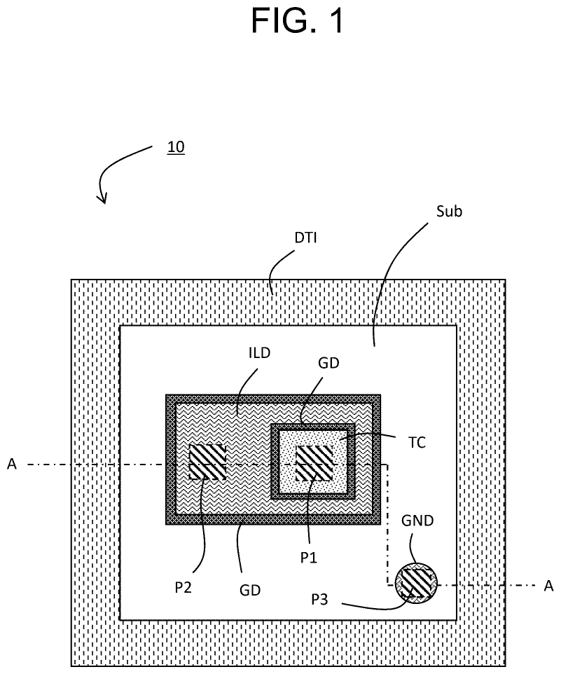

FIGS. 1-29 show vertical cross sections and horizontal cross sections. A vertical cross section is a cross section that is parallel to the thickness direction (in other words, the direction of lamination) in an image sensor 10. A horizontal cross section is a cross section that is perpendicular to the thickness direction in the image sensor 10.

FIGS. 1, 13, 21, 24, 26, and 29 show horizontal cross sections. In these figures, in order to facilitate understanding of the circuit structure, there are also shown configurations of plugs P1, P2, P3 and the like, which do not intersect the line indicating the cross section.

The image sensors 10 shown in FIGS. 1-29 are composed of, for example, CMOS image sensors.

### 1. First Embodiment

### 1-1. Structure

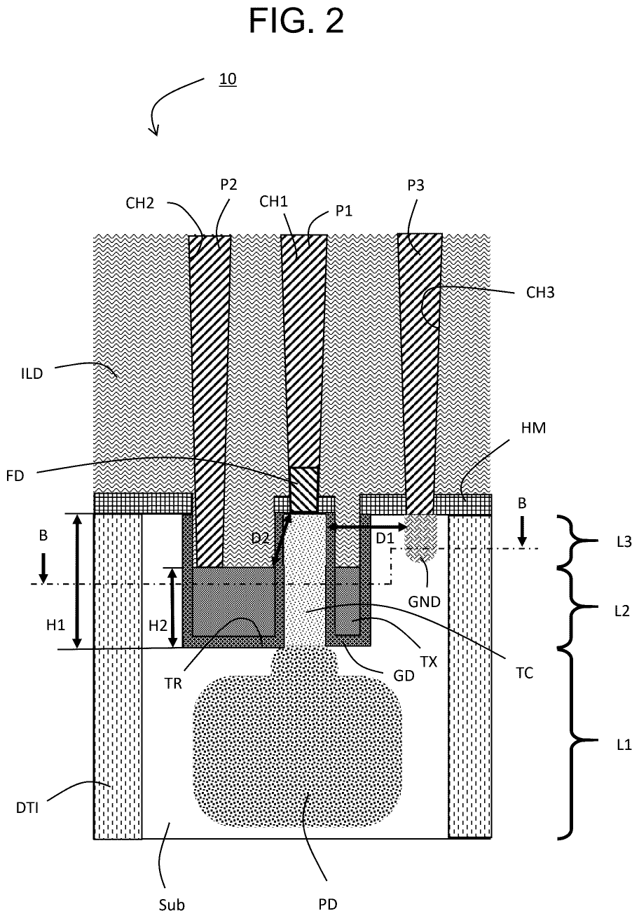

FIGS. 1 and 2 show an image sensor 10 according to a first embodiment. FIG. 1 shows a horizontal cross section taken along line B-B in FIG. 2. FIG. 2 shows a vertical cross section taken along line A-A in FIG. 1. The image sensor 10 is a so-called backside illuminated sensor, and has a photodiode PD formed in a lower layer L1 of a substrate Sub.

In an upper layer L3 of the substrate Sub and on top of the upper layer L3, a floating diffusion FD and a ground region GND are formed. Further, in an intermediate layer L2 between the lower layer L1 and the upper layer L3, a transfer gate TX is formed. As such, the substrate Sub has a vertical multilayer structure. For example, the substrate Sub is a P-type Si substrate.

A transfer channel TC is formed ranging across the intermediate layer L2 and the upper layer L3. The transfer channel TC has a lower end connected to the photodiode PD. An upper end of the transfer channel TC is connected to the floating diffusion FD. For example, the floating diffusion FD, the transfer channel TC, and the photodiode PD are linearly aligned in the thickness direction (i.e., the vertical direction) of the substrate Sub. Further, for example, the floating diffusion FD, the transfer channel TC, and the photodiode PD are arranged at the center in the plane of the substrate Sub.

For example, the photodiode PD is composed of any of a PN diode, a PIN diode, or an avalanche diode. The floating diffusion is composed of an epitaxial layer. That is, the floating diffusion is formed on top of the substrate Sub.

For example, the transfer channel TC is a P-type charge transfer channel. The transfer channel TC is doped using, for example, boron as impurities. The impurity concentration (i.e., the boron concentration) is higher than the impurity concentration in the P-type substrate Sub, and is lower than in the photodiode PD and in the floating diffusion FD. Alternatively, for example, the transfer channel TC is an N-type charge transfer channel. In that case, the transfer channel TC is doped using, for example, arsine or phosphorus as impurities. The impurity concentration is lower than in the photodiode PD and in the floating diffusion FD.

By configuring such that the impurity concentration in the transfer channel TC is higher than the impurity concentration in the substrate Sub, the transfer channel TC can be ensured as a charge transfer path inside the substrate Sub. Further, by configuring such that the impurity concentration in the transfer channel TC is lower than in the photodiode PD and in the floating diffusion FD, it is possible to suppress charge transfer from the photodiode PD to the floating diffusion FD at the time when no voltage is applied by the transfer gate TX. Even when the transfer channel TC is N-type, by controlling the OFF voltage of the transfer gate TX, it is possible to suppress charge transfer from the photodiode PD to the floating diffusion FD at the time when the transfer gate TX is in an OFF state.

The photodiode PD, the transfer channel TC, the floating diffusion FD, and the ground region GND are formed by adding impurities to the inside and the surface of the substrate Sub. These regions have various functions for outputting image information. Accordingly, where appropriate, these regions will be referred to below as “functional regions”.

The substrate Sub further has formed therein a trench TR. The trench TR surrounds the transfer channel TC in a tubular manner. For example, the trench TR is formed in a frame shape in plan view. Further, at a connection point of a plug P2, the trench TR is formed to have a relatively large groove width.

The trench TR is formed in the substrate Sub from the upper layer L3 reaching into the intermediate layer L2. For example, the trench TR is formed such that its depth H1 is larger than or equal to the thickness of the transfer channel TC. For example, the thickness of the transfer channel TC and the depth H1 of the trench TR are equal.

The surface of the trench TR is covered with a gate insulation film GD. In other words, the gate insulation film GD is formed at the two side surfaces and the bottom surface of the trench TR. The gate insulation film GD is composed of a so-called high-k material or an oxide film, or a laminate film formed of the foregoing. For example, the gate insulation film GD is composed of a laminate film formed of HfSiO, HfAION, HfO₂, and SiO₂.

By forming the gate insulation film GD at the side surfaces of the trench TR, the transfer channel TC is enclosed in a tubular manner by an insulation film. For example, side surfaces of the transfer channel TC are covered with the gate insulation film GD in a tubular manner over the entire length in the thickness direction. By enclosing the transfer channel TC in a tubular manner with an insulation film, it is possible to suppress leakage current between the transfer channel TC and parts such as outside electrodes and the functional regions.

It is noted that a lower end portion of the transfer channel TC is located near the lower layer L1. That is, the lower end portion of the transfer channel TC and the ground region GND are sufficiently spaced apart in the thickness direction. Since a sufficient inter-regional distance (which may also be referred to as “distance between elements”) is thus provided, it is not necessary to cover the lower end portion of the transfer channel TC with an insulation film. In other words, it is sufficient so long as at least an upper portion of the transfer channel TC is covered with an insulation film. Here, the upper portion denotes, for example, the portion located in the upper layer L3 of the substrate Sub.

On top of the gate insulation film GD, the transfer gate TX is formed. For example, the transfer gate TX is composed of a metal gate. The transfer gate TX is formed along the shape of the trench so as to have a frame shape, and the transfer gate TX surrounds the transfer channel TC. At a connection point with the plug P2, the transfer gate TX protrudes toward the outer periphery of the substrate Sub. With this feature, the plug P2 and the floating diffusion FD can be isolated from each other in the surface direction (i.e., the horizontal direction). It is thereby possible to reduce parasitic capacitance that occurs between the plug P2 and the floating diffusion FD.

The depth H1 of the trench TR exceeds the thickness H2 of the transfer gate TX. Here, the thickness H2 ignores the thickness of the gate insulation film GD. The transfer gate TX is formed at the bottom part of the trench TR. In this structure, the transfer gate TX and the floating diffusion FD are isolated from each other in the thickness direction, as indicated by distance D2 in FIG. 2.

As such, by cutting the trench TR deeper than the thickness of the transfer gate TX, a sufficient inter-regional distance (or distance between elements) between the transfer gate TX and the floating diffusion FD is ensured. Furthermore, the shortest path D2 between the transfer gate TX and the floating diffusion FD is blocked by the gate insulation film GD. Accordingly, leakage current between the floating diffusion FD and the transfer gate TX is suppressed.

The ground region GND is formed at a position closer to a peripheral edge of the substrate Sub than is the trench TR. For example, the ground region GND is formed as an embedded layer in the upper layer L3 of the substrate Sub. For example, a P+ layer, which has a higher concentration of P-type impurities such as boron and indium than the P-type substrate, serves as the ground region GND. The ground region GND is connected to the plug P3. That is, the ground region GND is maintained at ground potential.

For example, the ground region GND is formed between the transfer gate TX and an element-isolating insulation film DTI. Accordingly, the gate insulation film GD is located between the ground region GND and the transfer channel TC.

As shown in FIG. 2, the shortest path D1 between the transfer channel TC and the ground region GND is blocked by the gate insulation film GD. Accordingly, leakage current between the transfer channel TC and the ground region GND is suppressed. In addition, the transfer channel TC is enclosed in a tubular manner by the gate insulation film GD. Accordingly, paths that bypass the shortest path D1 are also blocked by the gate insulation film GD. As a result, leakage current between the transfer channel TC and the ground region GND is suppressed.

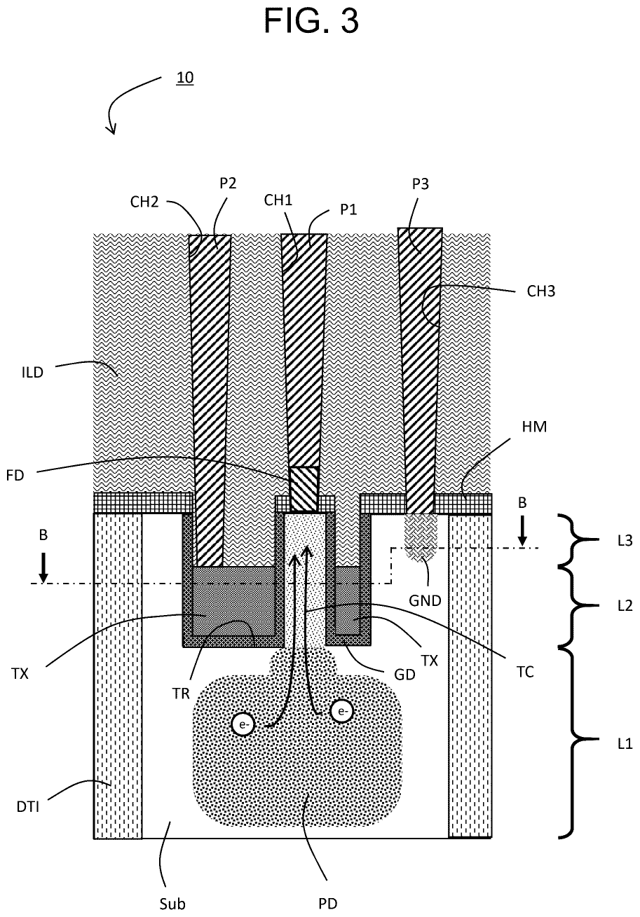

Referring to FIG. 3, charges accumulated in the photodiode PD are transferred to a logic circuit (not shown in drawing) via the transfer channel TC and the floating diffusion FD. For example, at the time of readout, a voltage is applied to the transfer gate TX. At that time, a depletion layer is generated in the transfer channel TC surrounded by the frame-shaped transfer gate TX. The charges accumulated in the photodiode PD are drawn out through the transfer channel TC into the floating diffusion FD.

As described above, in the image sensor according to the first embodiment, the shortest path D1 between the transfer channel TC and the ground region GND is blocked by the gate insulation film GD. In a similar manner, the shortest path D2 between the floating diffusion FD and the transfer gate TX is also blocked by the gate insulation film GD.

Further, the transfer channel TC is enclosed in a tubular manner by the gate insulation film GD. Accordingly, paths that bypass the shortest paths D1, D2 are also blocked by the gate insulation film GD. By providing such a structure, it is possible to suppress leakage current flowing from the charge transfer path, which extends from the photodiode PD to the floating diffusion FD via the transfer channel TC, to nearby electrodes and functional regions.

### 1-2. Manufacturing Process

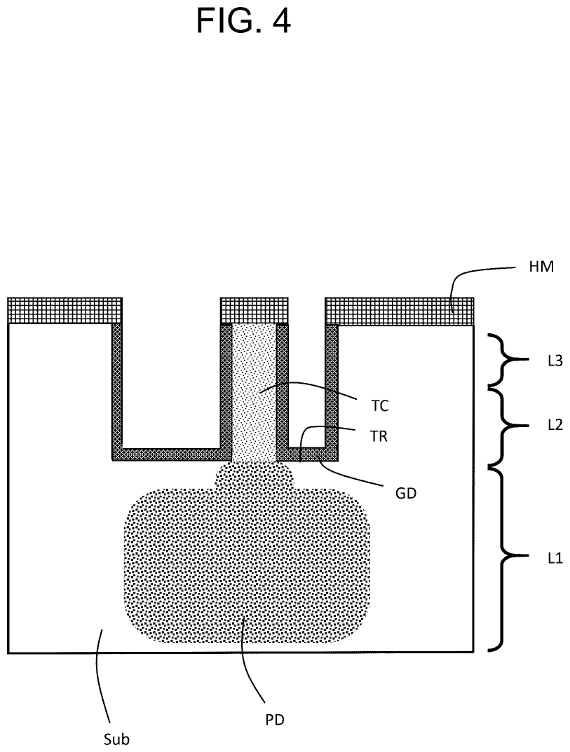

FIGS. 4-12 illustrate a manufacturing process of the image sensor 10 according to the first embodiment. Referring to FIG. 4, the photodiode PD is formed in the lower layer L1 of the substrate Sub. Further, the transfer channel TC is formed ranging across the upper layer L3 and the intermediate layer L2. The lower end of the transfer channel TC is connected to the photodiode PD.

Next, a hard mask HM is formed on the substrate Sub. An opening is formed in the hard mask HM at a position corresponding to the trench TR. By etching the substrate Sub in that state, the trench TR is formed surrounding the transfer channel TC. Further, by oxidizing the surfaces of the trench TR; namely, the two side surfaces and the bottom surface of the trench TR, the gate insulation film GD is obtained.

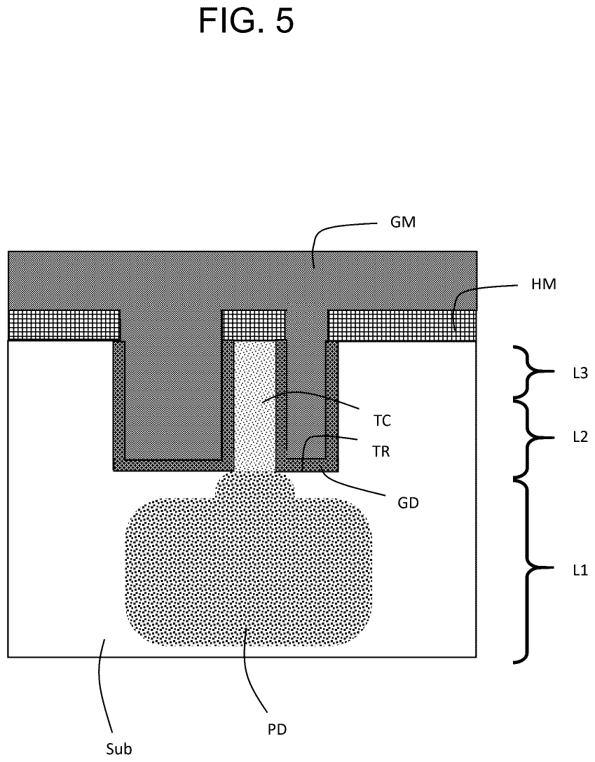

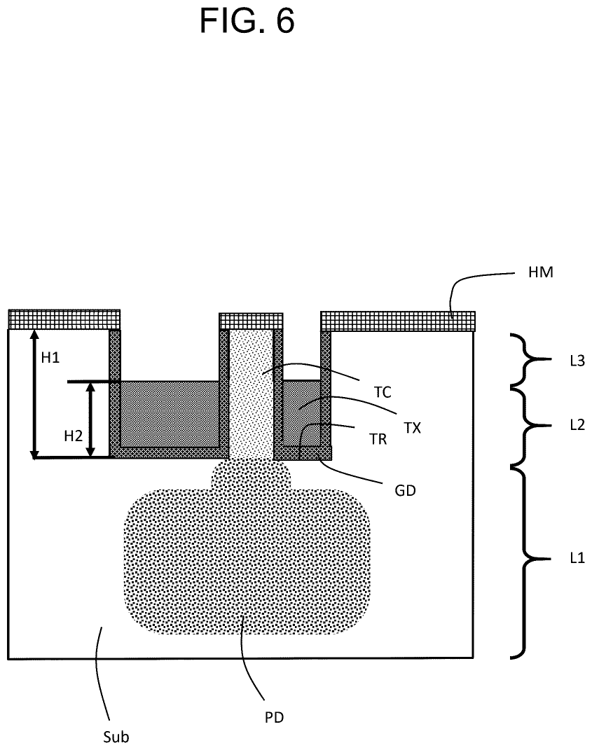

Referring to FIG. 5, a gate metal GM is laminated on the substrate Sub. Next, referring to FIG. 6, the part above the hard mask HM is planarized by chemical mechanical polishing (CMP). Further, the gate metal GM located in the upper layer L3 is removed by etching. As a result, the transfer gate TX is obtained, which has a layer thickness smaller than the groove depth of the trench TR.

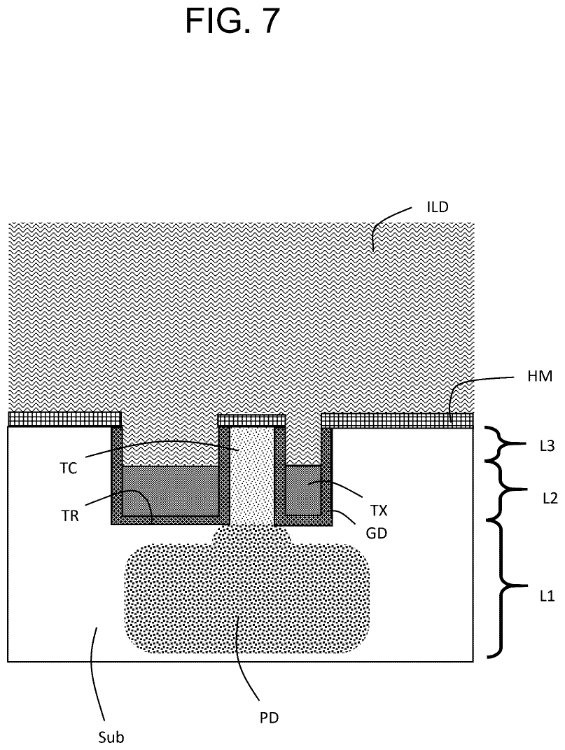

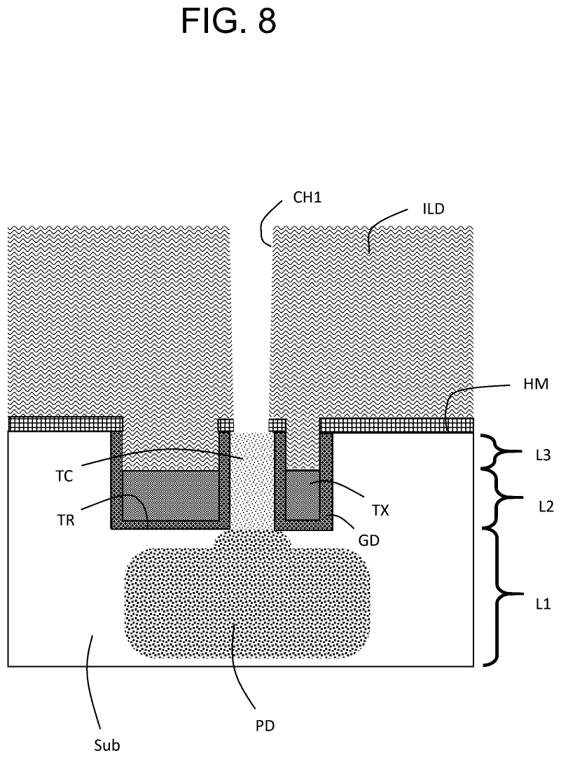

Referring to FIG. 7, an interlayer insulation film ILD is formed on the substrate Sub. For example, the interlayer insulation film ILD is composed of SiO₂ and Si₃N₄. Next, referring to FIG. 8, a contact hole CH1 is formed at a position above the transfer channel TC. The contact hole CH1 penetrates the interlayer insulation film ILD and the hard mask HM, and reaches the upper end of the transfer channel TC.

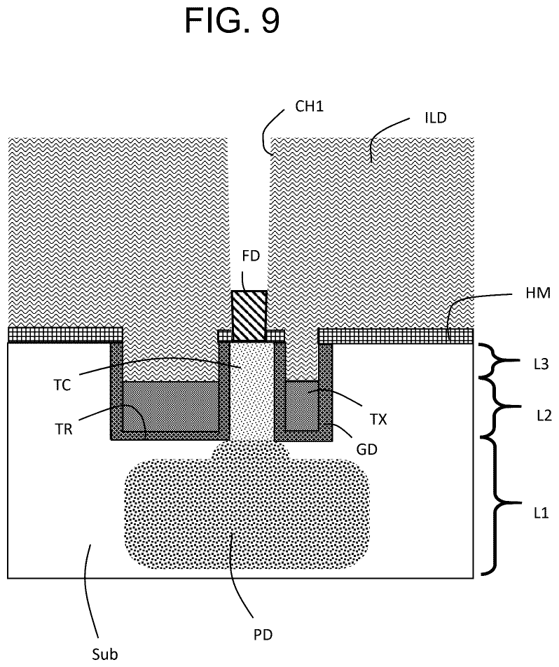

Referring to FIG. 9, the floating diffusion FD is formed on top of the upper layer L3 of the substrate Sub by epitaxial growth. For example, the floating diffusion FD is formed by vapor phase epitaxy (VBE or CVD).

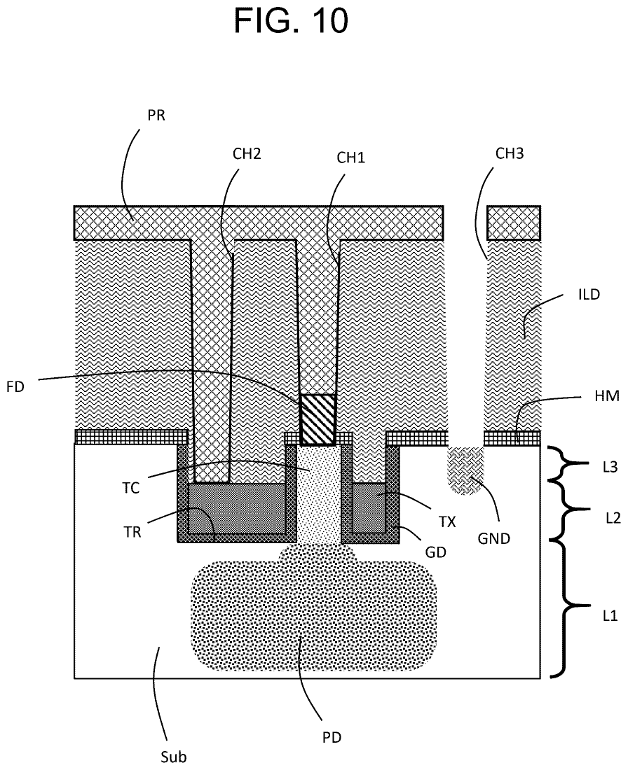

Referring to FIG. 10, a photoresist PR is applied on top of the interlayer insulation film ILD. An opening is formed in the photoresist PR at a position corresponding to the ground region GND. By subsequently performing etching, a contact hole CH3 is formed in the interlayer insulation film ILD. The contact hole CH3 penetrates the interlayer insulation film ILD and the hard mask HM, and reaches the upper layer L3 of the substrate Sub.

Next, the ground region GND is formed in the upper layer L3 by ion implantation. As such, into the ground region, impurities are implanted through the contact hole CH3. Accordingly, the region diameter of the ground region GND becomes equal to the hole diameter of the contact hole CH3.

For example, if an attempt is to be made to form the ground region GND on the substrate Sub without using the contact hole CH3, a photoresist would be applied on the substrate Sub, then an opening would be formed in the photoresist at a portion to be exposed. For example, if the exposure light source is a krypton-fluorine (KrF) laser light source, based on the light source wavelength (248 nm), the opening diameter would be approximately 0.2 μm. In contrast, when the contact hole CH3 is formed for example by dry etching, the contact hole CH3 can be formed to have a smaller diameter than an opening formed by a krypton-fluorine laser light source. By thus forming the ground region GND to have a small diameter, an increase in inter-regional distance (or distance between elements) can be suppressed.

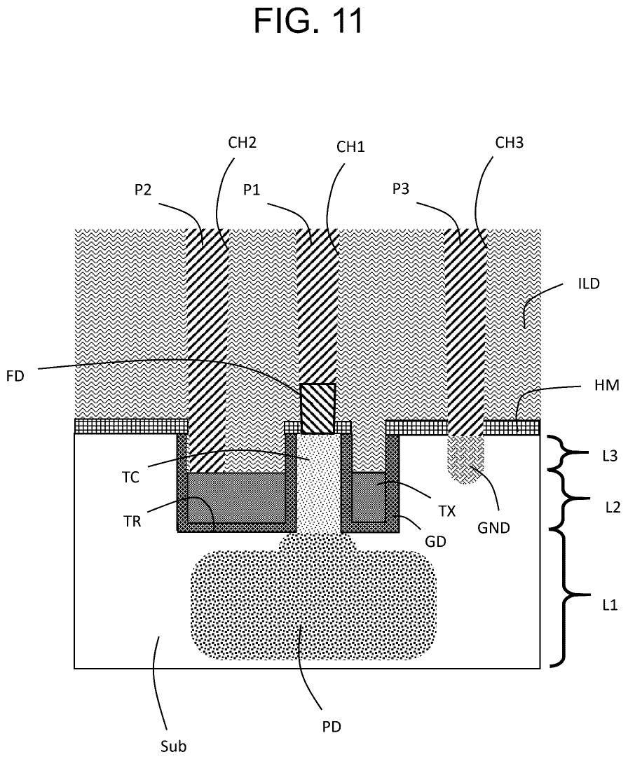

Referring to FIG. 11, in addition to the contact holes CH1, CH3, a contact hole CH2 extending to the transfer gate TX is formed in the interlayer insulation film ILD. Next, the contact holes CH1, CH2, CH3 are filled with the plugs P1, P2, P3. The plugs P1, P2, P3 are connected to a logic circuit unit (not shown in drawing).

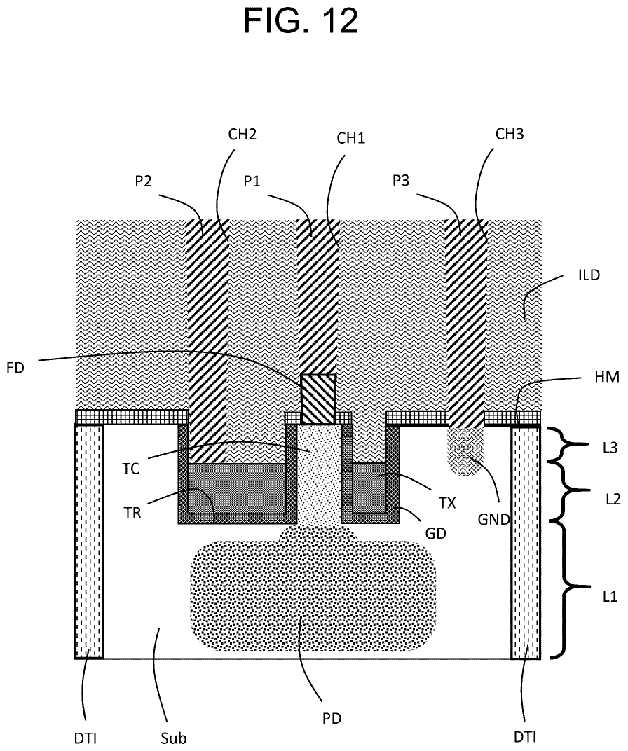

Referring to FIG. 12, the element-isolating insulation film DTI is formed at the edges of the substrate Sub. As shown in FIGS. 1 and 2, the element-isolating insulation film DTI surrounds the photodiode PD, the transfer channel TC, the floating diffusion FD, the transfer gate TX, and the ground region GND. By means of the element-isolating insulation film DTI, the image sensor 10 is isolated from adjacent image sensors 10. That is, transfer of charges accumulated in the photodiode PD to an adjacent photodiode PD is suppressed by the element-isolating insulation film DTI.

### 2. Second Embodiment (L-Shaped TX)

### 2-1. Structure

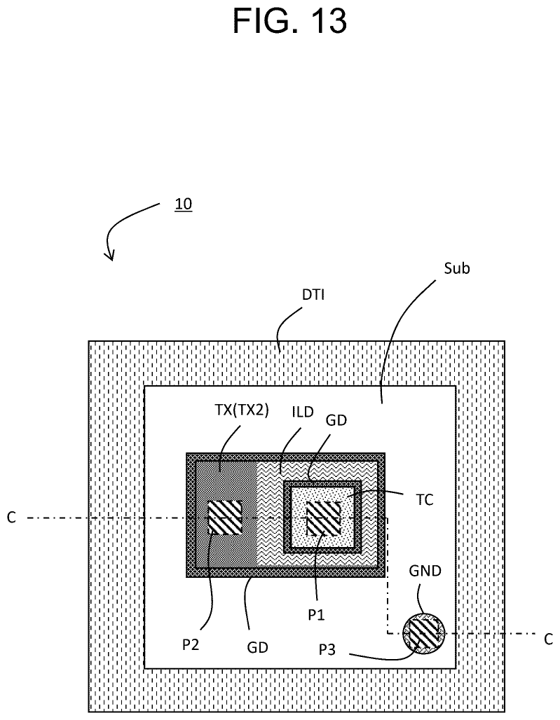

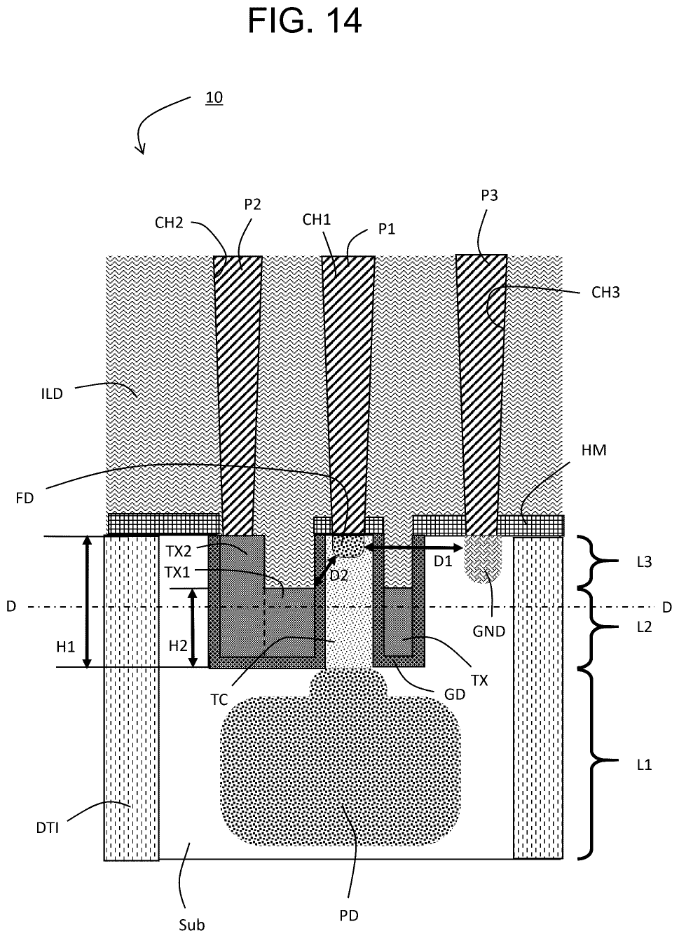

FIGS. 13 to 20 show an image sensor 10 according to a second embodiment. The image sensor 10 according to the second embodiment differs from the image sensor 10 of the first embodiment in that the floating diffusion FD is composed of an embedded layer (see FIG. 14), and in that the transfer gate TX is formed to have an L-shaped vertical cross section. Other than these two points, the configuration is identical to that of the first embodiment.

Referring to FIG. 14, the floating diffusion FD, which is an embedded layer, is formed inside the upper layer L3 of the substrate Sub. In this case, the shortest path D1 between the location of the floating diffusion FD and the transfer channel TC and the location of the ground region GND is blocked by the gate insulation film GD.

Further, in adaptation to the floating diffusion FD being formed inside the upper layer L3, the transfer gate TX is formed in a shape capable of ensuring a sufficient distance in the thickness direction from the floating diffusion FD.

That is, the transfer gate TX is formed such that its vertical cross section is L-shaped. Referring to FIG. 14, the transfer gate TX comprises a main part TX1 and a connection part TX2. The main part TX1 is formed in a region relatively close to the floating diffusion FD. For example, the main part TX1 is formed in a frame shape along the trench TR.

The connection part TX2 is a portion to be connected to the plug P2. The connection part TX2 is formed in a region relatively far from the floating diffusion FD. For example, the connection part TX2 is a rectangular solid region located on the outside of the main part TX1.

The main part TX1 is formed to have a smaller thickness compared to the connection part TX2. For example, referring to FIG. 14, the thickness H2 of the connection part TX2 and the thickness H1 of the main part TX1 are defined as H1>H2. In FIG. 14, the thicknesses H1, H2 are shown ignoring the thickness of the gate insulation film GD.

As described above, the transfer gate TX is formed at the bottom part of the trench TR. By forming the main part TX1 to have a small thickness, a sufficient isolation distance in the thickness direction can be ensured between the floating diffusion FD, which is an embedded layer, and the main part TX1. Further, the connection part TX2 is isolated from the floating diffusion FD in the surface direction (i.e., the horizontal direction). With these isolation features, it is possible to reduce parasitic capacitance that occurs between the transfer gate TX and the floating diffusion FD.

The connection part TX2 is isolated from the floating diffusion FD in the in-plane direction (i.e., the direction orthogonal to the depth direction). In addition, for example, by forming the connection part TX2 to have a thickness approximately equal to the depth of the trench TR, connection between the connection part TX2 and the plug P2 is facilitated.

### 2-2. Manufacturing Process

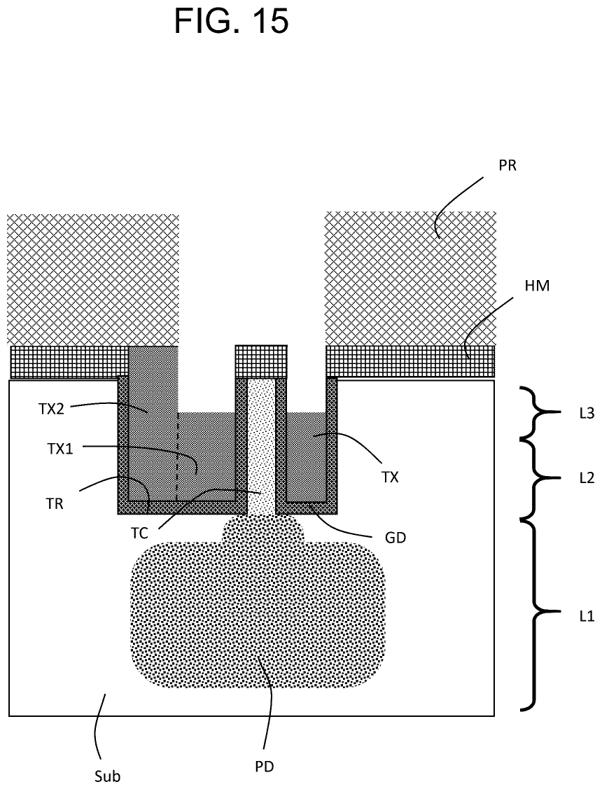

In a manufacturing process of the image sensor 10 according to the second embodiment, after performing the steps shown in FIGS. 4 and 5, the process proceeds to the step shown in FIG. 15. After the gate metal GM is laminated in the step of FIG. 5, the gate metal GM located above the hard mask HM is removed by chemical mechanical polishing (CMP). After that, a photoresist PR is laminated on top of the hard mask HM.

Referring to FIG. 15, an opening is formed in a part of the photoresist PR. That is, an opening is formed in a rectangular region corresponding to the main part TX1. On top of the connection part TX2, the photoresist PR remains laminated. By subsequently performing etching, the gate metal inside the trench TR is etched, and the main part TX1 is thereby formed.

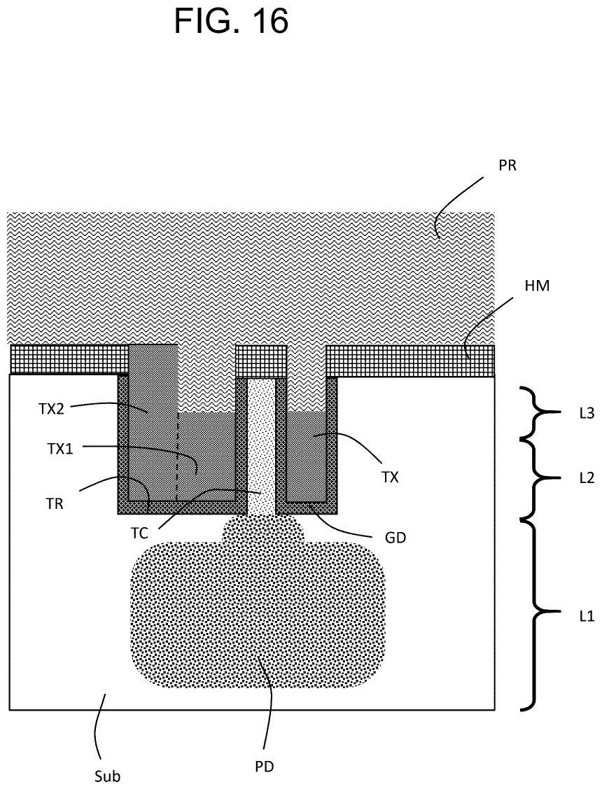

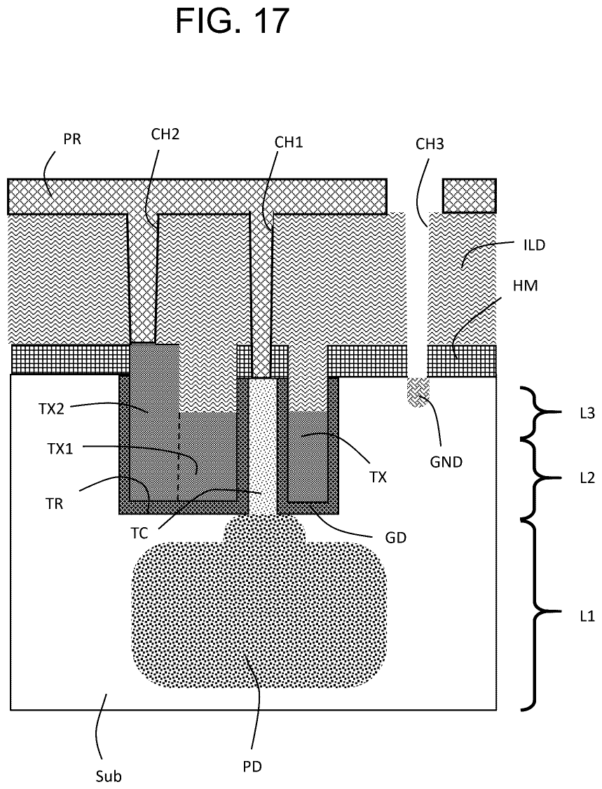

Referring to FIG. 16, after removing the photoresist PR, an interlayer insulation film ILD is laminated on top of the hard mask HM. Referring to FIG. 17, contact holes CH1, CH2, CH3 are formed in the interlayer insulation film ILD. The contact hole CH1 penetrates the hard mask HM and reaches the upper end of the transfer channel TC. The contact hole CH2 reaches the upper end of the connection part TX2. The contact hole CH3 is formed in the interlayer insulation film ILD at a position corresponding to the ground region GND. The contact hole CH3 penetrates the hard mask HM.

A photoresist PR is laminated on top of the interlayer insulation film ILD and also filled in the contact holes CH1, CH2. In the photoresist PR, the contact hole CH3 is opened. Next, the ground region GND is formed by ion implantation. That is, the ground region GND is formed as an embedded layer in the upper layer L3 of the substrate Sub.

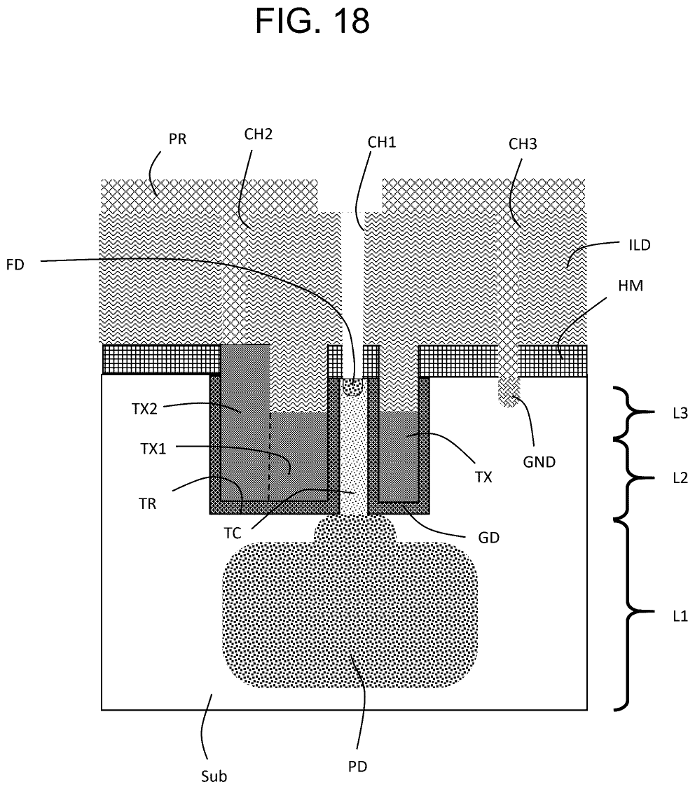

Subsequently, the photoresist PR is removed. Next, referring to FIG. 18, a photoresist PR is newly laminated on top of the interlayer insulation film ILD and also filled in the contact holes CH2, CH3. In the photoresist PR, the contact hole CH1 is opened. Next, the floating diffusion FD is formed by ion implantation. That is, the floating diffusion FD is formed as an embedded layer in the upper layer L3 of the substrate Sub.

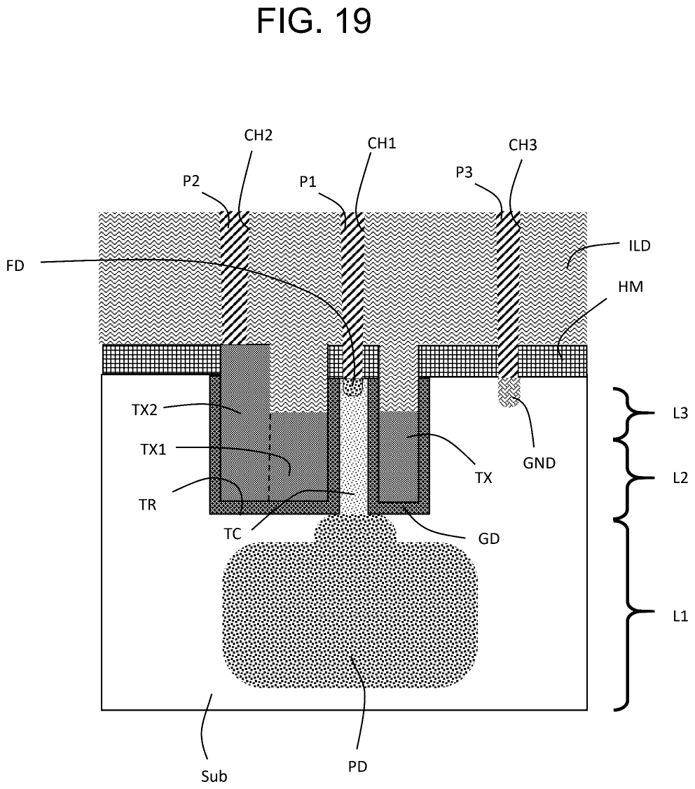

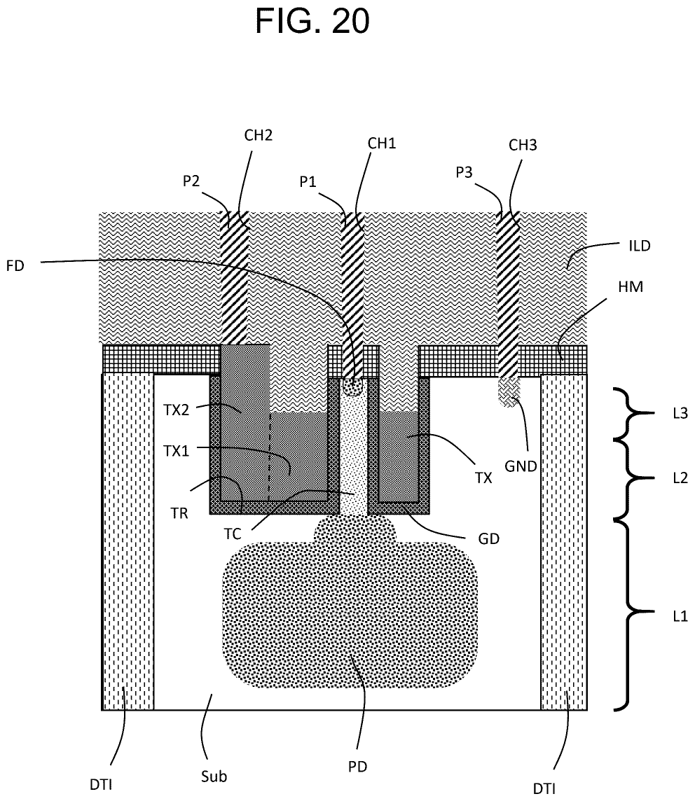

Referring to FIG. 19, after removing the photoresist PR, plugs P1, P2, P3 are formed in the contact holes CH1, CH2, CH3. Referring to FIG. 20, the element-isolating insulation film DTI is formed at the edges of the substrate Sub.

### 3. Third Embodiment (FD as Embedded Layer)

### 3-1. Structure

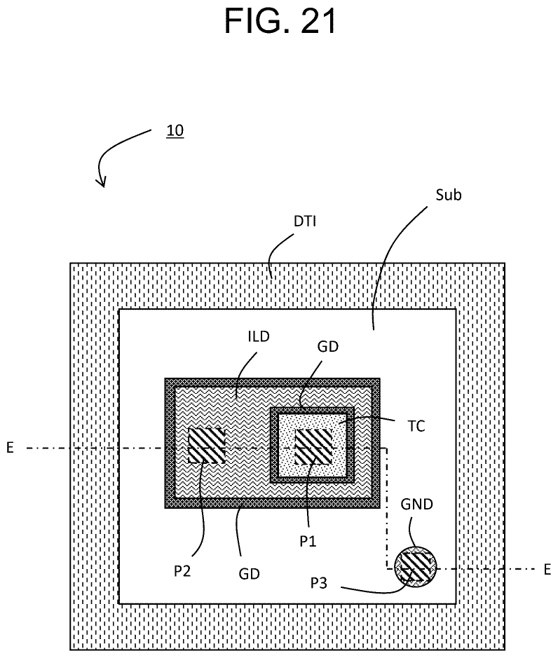

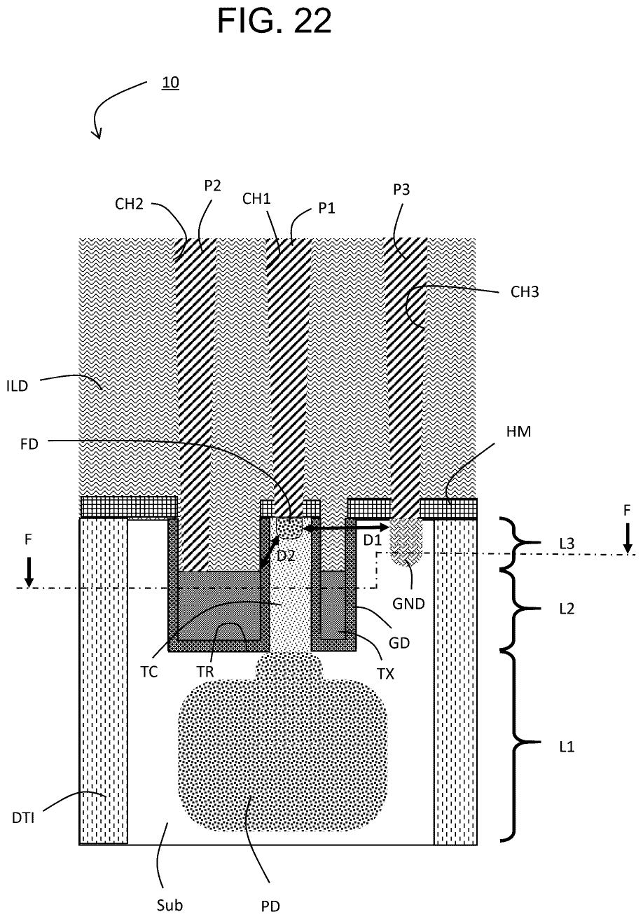

FIGS. 21 and 22 show an image sensor 10 according to a third embodiment. In contrast to the first embodiment, the image sensor 10 according to the third embodiment is such that the floating diffusion FD is formed by ion implantation instead of by epitaxial growth. In other words, the floating diffusion FD is an embedded layer, and is formed inside the upper layer L3 of the substrate Sub. Other structures are identical with those of the first embodiment.

Likewise in this embodiment, the shortest path D1 between the location of the floating diffusion FD and the transfer channel TC and the location of the ground region GND is blocked by the gate insulation film GD.

Further, the depth of the trench TR exceeds the thickness of the transfer gate TX, and the transfer gate TX is formed at the bottom part of the trench TR. The contact hole CH2 extends deeper than the floating diffusion FD, and reaches the transfer gate TX.

In this structure, the transfer gate TX and the floating diffusion FD are isolated from each other in the thickness direction, as indicated by distance D2 in FIG. 22. That is, a sufficient electrode-region distance (or distance between elements) between the transfer gate TX and the floating diffusion FD is provided. Further, the shortest path D2 between the transfer gate TX and the floating diffusion FD is blocked by the gate insulation film GD.

### 3-2. Manufacturing Process

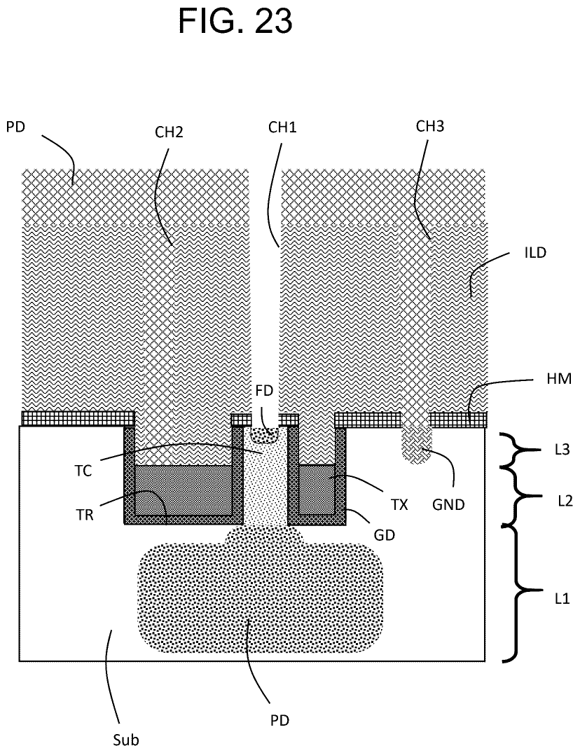

In a manufacturing process of the image sensor 10 according to the third embodiment, the step shown in FIG. 9 is replaced by a step shown in FIG. 23. Otherwise, the same steps as in FIGS. 4-13 are executed.

In FIG. 23, ion implantation is performed in the upper end of the transfer channel TC exposed by the contact hole CH1. As a result, the floating diffusion FD is formed inside the upper layer L3 of the substrate Sub.

### 4. Fourth Embodiment (TC Surrounded by GD and DTI)

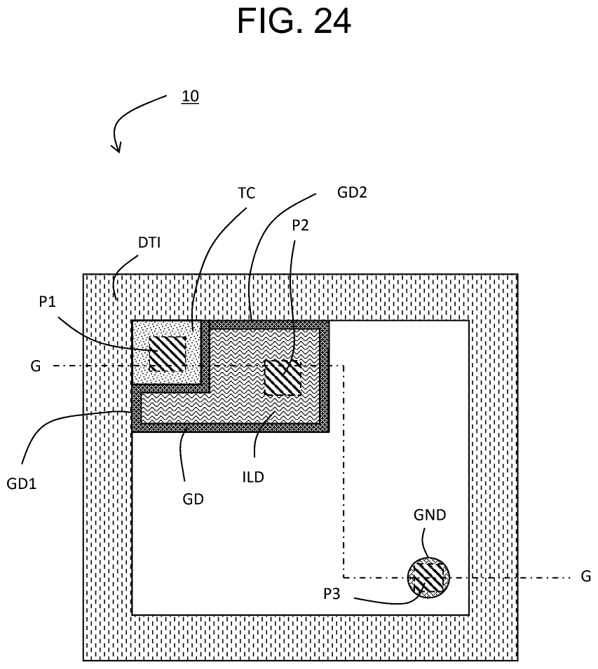

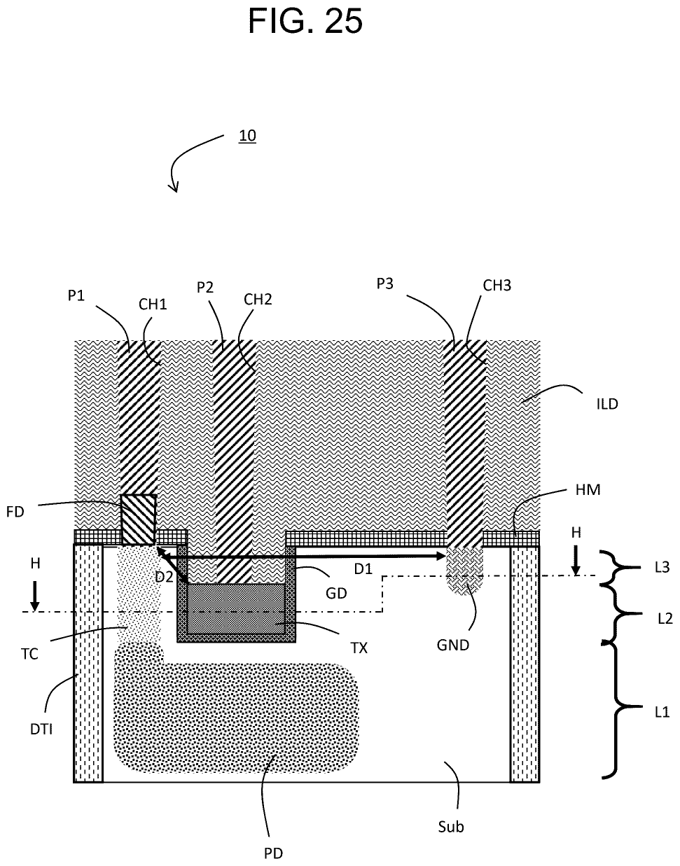

FIGS. 24 and 25 show an image sensor 10 according to a fourth embodiment. While the transfer channel TC is enclosed in a tubular manner by the gate insulation film GD in the first to third embodiments, according to the fourth embodiment, the transfer channel TC is enclosed in a tubular manner by a combination of the gate insulation film GD and the element-isolating insulation film DTI.

In the image sensor 10 according to the fourth embodiment, the positions of the transfer channel TC and the floating diffusion FD in the substrate Sub are different from those in the image sensor 10 according to the first embodiment. In addition, the shape of the transfer gate TX is also different between the first embodiment and the fourth embodiment. However, despite such differences in position and shape, the image sensor 10 according to the fourth embodiment is manufactured essentially based on the steps shown in FIGS. 4 to 12.

Referring to FIGS. 24 and 25, the transfer channel TC is formed at a corner part of a substrate Sub having a rectangular shape in plan view. Further, the transfer gate TX is formed adjacent to the transfer channel TC in the surface direction. Here, the surface direction is the direction perpendicular to the thickness direction.

First, the trench TR is formed near the transfer channel TC. The trench TR is L-shaped in plan view. The gate insulation film GD is formed at the side surfaces and the bottom surface of the trench TR. Next, the transfer gate TX is formed on top of the gate insulation film GD at the bottom part of the trench TR. Based on the shape of the trench TR, the gate insulation film GD and the transfer gate TX are formed to have an L shape in plan view.

After the floating diffusion FD is formed on top of the transfer channel TC, the element-isolating insulation film DTI is formed at the edges of the substrate Sub. The element-isolating insulation film DTI surrounds the photodiode PD, and serves to suppress charge transfer to adjacent photodiodes. The element-isolating insulation film DTI is formed in contact with edges GD1, GD2 (see FIG. 24) of the gate insulation film GD.

According to the above-described configuration, the transfer channel TC is located on the inside of an insulation film arrangement having the shape of a rectangular frame. An L-shaped structure, which is a part of the rectangular frame, is formed by the gate insulation film GD. The remaining L-shaped structure of the rectangular frame is formed by the element-isolating insulation film DTI. In other words, the transfer channel TC is enclosed in a tubular manner by the gate insulation film GD and the element-isolating insulation film DTI.

Further, referring to FIG. 24, the ground region GND is provided diagonally across from the transfer channel TC. Since the substrate Sub has a rectangular shape in plan view, the transfer channel TC is formed at one corner of the rectangular shape, and the ground region GND is formed at a corner located diagonally opposite to the one corner.

As such, on the rectangular substrate Sub, the transfer channel TC and the ground region GND are formed at corners diagonally opposite to each other. With this feature, as shown in FIG. 25, the shortest path D1 between the transfer channel TC and the ground region GND is significantly extended as compared to the shortest path D1 in the image sensor 10 according to the first embodiment.

In addition, likewise in this fourth embodiment, the shortest path D1 between the location of the floating diffusion FD and the transfer channel TC and the location of the ground region GND is blocked by the gate insulation film GD. Further, the depth of the trench TR exceeds the thickness of the transfer gate TX, and the transfer gate TX is formed at the bottom part of the trench TR. In this structure, a sufficient electrode-region distance (or distance between elements) D2 between the transfer gate TX and the floating diffusion FD is ensured.

### 5. Fifth Embodiment (TC Surrounded by a Plurality of TXs)

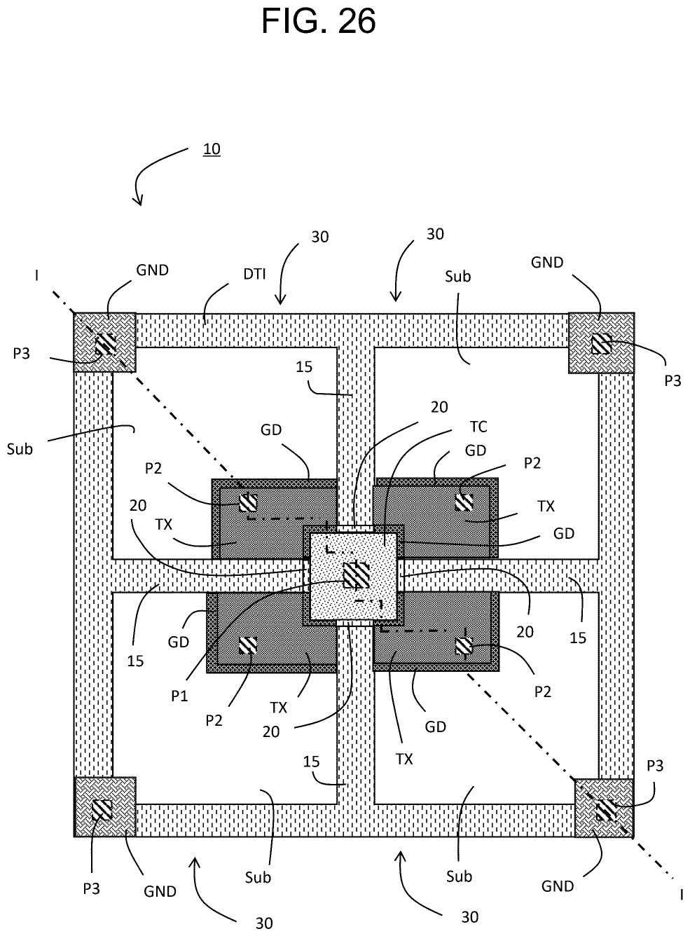

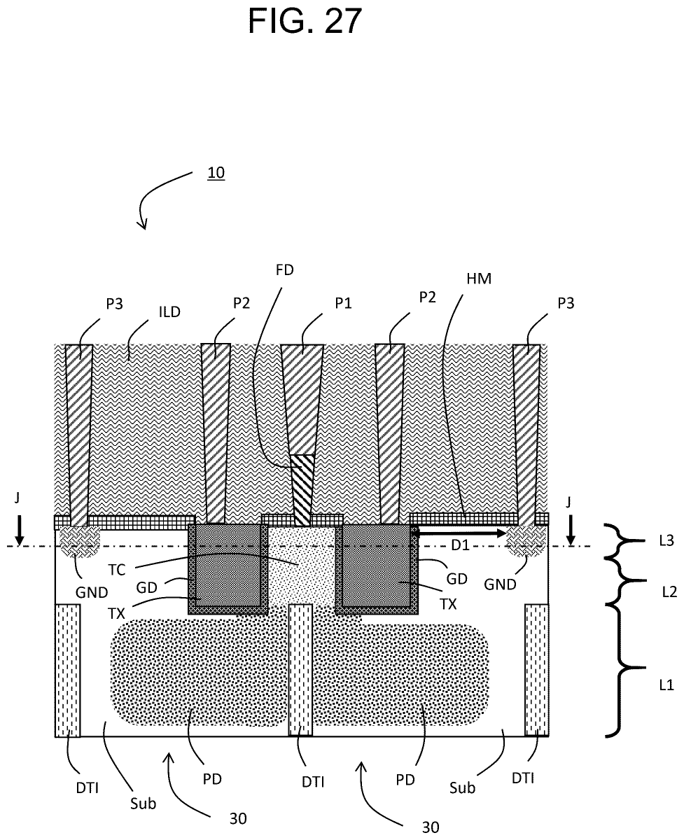

FIGS. 26 and 27 show an image sensor 10 according to a fifth embodiment. This image sensor 10 comprises a plurality of photoelectric conversion units 30.

Each photoelectric conversion unit 30 comprises a photodiode PD, a transfer gate TX, a gate insulation film GD, and an element-isolating insulation film DTI. For example, the photoelectric conversion unit 30 is rectangular in plan view. The photodiode PD is surrounded by the element-isolating insulation film DTI. The transfer gate TX is provided along one corner of the frame-shaped element-isolating insulation film DTI.

The image sensor 10 comprises a plurality of such photoelectric conversion units 30, a single transfer channel TC, and a single floating diffusion FD. The single transfer channel TC and the single floating diffusion FD are surrounded by the plurality of photoelectric conversion units 30.

More specifically, a total of four photoelectric conversion units 30 are arranged in a matrix. The image sensor 10 is thereby formed to have a rectangular shape.

Further, at a central part in the plane of the image sensor 10, the transfer channel TC and the floating diffusion FD are formed. Portions 15 of the element-isolating insulation film DTI which extend toward the center of the image sensor 10 terminate at the transfer channel TC.

In each of the pixel units, the ground region GND is formed. Each ground region GND is provided at a corner diagonally across from the transfer channel TC. In other words, within each pixel unit, the ground region GND and the transfer channel TC are formed at positions farthest apart from each other.

Since the ground region GND is formed at a point of intersection of the element-isolating insulation film DTI as shown in FIGS. 26 and 27, the element-isolating insulation film DTI is formed in the lower layer L1 of the substrate Sub but not in the intermediate layer L2 or the upper layer L3, as shown in FIG. 27.

Accordingly, each of the portions 15 of the element-isolating insulation film DTI extending toward the center of the image sensor 10 may have an extension wall 20 formed at its end reaching the transfer channel TC. The extension wall 20 extends inside the substrate Sub up to the hard mask HM. With this feature, the transfer channel TC is enclosed in a tubular manner by the gate insulation film GD and the element-isolating insulation film DTI, as shown in FIG. 26.

Referring to FIG. 27, likewise in this fifth embodiment, the shortest path D1 between the location of the floating diffusion FD and the transfer channel TC and the location of the ground region GND is blocked by the gate insulation film GD.

### 6. Sixth Embodiment (GND Formed by Epitaxial Growth)

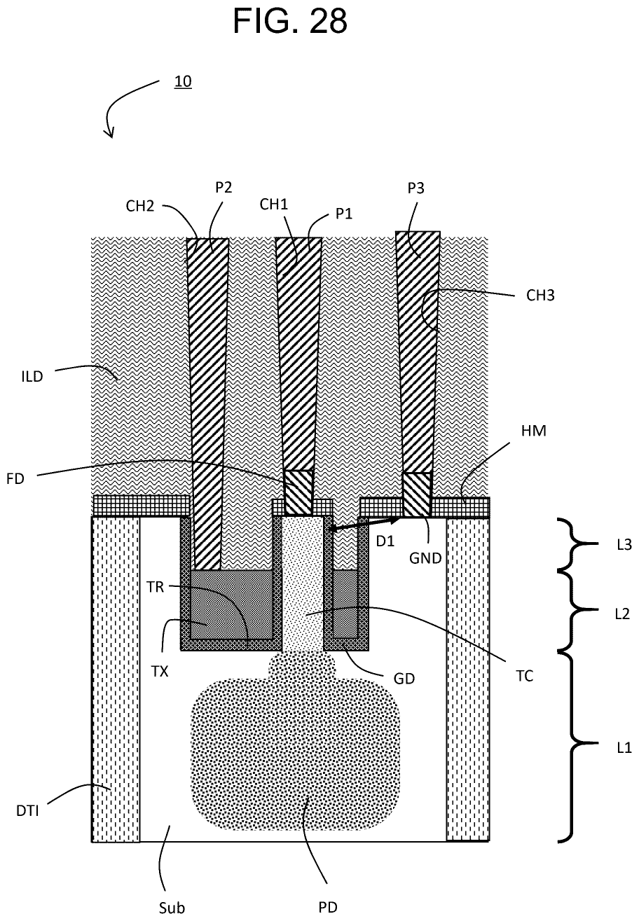

FIG. 28 shows an image sensor 10 according to a sixth embodiment. Its difference from the image sensor 10 according to the first embodiment is that the ground region GND is formed by epitaxial growth instead of by ion implantation. In other words, in this embodiment, both the floating diffusion FD and the ground region GND are epitaxial layers, and both are formed on top of the upper layer L3 of the substrate Sub. Likewise in this embodiment, the shortest path D1 between the transfer channel TC and the ground region GND is blocked by the gate insulation film GD.

### 7. Seventh Embodiment (Pixel Unit and Logic Circuit Unit in Parallel Arrangement)

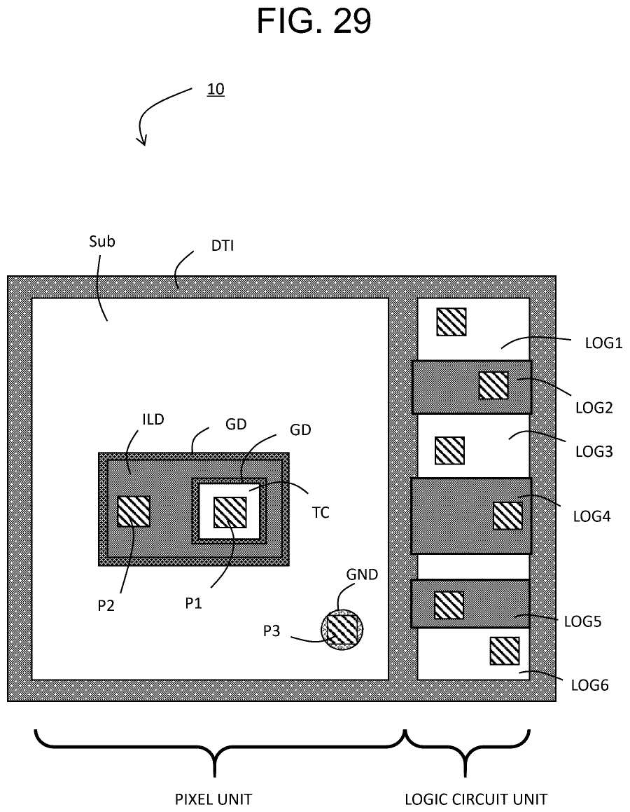

FIG. 29 shows an image sensor 10 according to a seventh embodiment. In this image sensor, a pixel unit and a logic circuit unit are formed within the same plane. For example, the pixel unit has a structure identical to that of the first embodiment. The logic circuit unit is formed adjacent to the pixel unit. In the logic circuit unit, a plurality of logic circuit regions LOG1 to LOG 6 are formed. The logic circuit regions LOG1 to LOG 6 are logic circuit regions of a CMOS image sensor, which are composed of, for example, a source follower transistor, a row selector, a reset transistor, and the like.

The present disclosure is not limited to the present embodiments described above, and includes all changes and modifications without departing from the technical scope or the essence of the present disclosure defined by the claims.

1. An image sensor including a substrate having a multilayer structure, the image sensor comprising:
a photodiode formed in a lower layer of the substrate;
a floating diffusion and a ground region, each of which is formed in or on top of an upper layer of the substrate;
a transfer channel having a lower end connected to the photodiode and an upper end connected to the floating diffusion; and
an insulation film blocking at least a shortest path between the transfer channel and the ground region.

2. The image sensor according to claim 1, wherein
a trench is formed, which has a frame shape that surrounds the transfer channel,
a gate insulation film is formed at least at a side surface of the trench, and
the transfer channel is enclosed in a tubular manner by the gate insulation film.

3. The image sensor according to claim 2, wherein
the gate insulation film is formed at a bottom surface of the trench in addition to at the side surface,
a transfer gate is formed on top of the gate insulation film,
a depth of the trench exceeds a thickness of the transfer gate, and
the transfer gate is formed at a bottom part of the trench.

4. The image sensor according to claim 3, wherein
the floating diffusion is an epitaxial layer.

5. The image sensor according to claim 1, wherein
the transfer channel has a lower impurity concentration than the floating diffusion and the photodiode.

6. The image sensor according to claim 3, wherein
the floating diffusion is an embedded layer, and
a region of the transfer gate that is relatively close to the floating diffusion has a smaller layer thickness than a region of the transfer gate that is relatively far from the floating diffusion.

7. The image sensor according to claim 3, wherein
the floating diffusion is an embedded layer, and
a contact hole is formed, which extends deeper than the floating diffusion and reaches the transfer gate.

8. The image sensor according to claim 1, further comprising:
a transfer gate located adjacent to the transfer channel in a surface direction; and
an element-isolating insulation film that surrounds the photodiode, wherein
the transfer channel is enclosed in a tubular manner by the gate insulation film and the element-isolating insulation film.

9. The image sensor according to claim 8, comprising
a photoelectric conversion unit including the photodiode, the transfer gate, the gate insulation film, and the element-isolating insulation film, wherein
the image sensor includes a plurality of such photoelectric conversion units, and a single such transfer channel and a single such floating diffusion which are surrounded by the plurality of photoelectric conversion units.

10. The image sensor according to claim 4, wherein
the ground region is an epitaxial layer.

11. A manufacturing method of an image sensor including a substrate having a multilayer structure, the image sensor manufacturing method comprising:
forming a photodiode in a lower layer of the substrate;
forming a transfer channel such that its lower end is connected to the photodiode;
forming a floating diffusion in or on top of an upper layer of the substrate such that an upper end of the transfer channel is connected thereto; and
forming a ground region in or on top of the upper layer, wherein
the image sensor manufacturing method further comprises forming an insulation film which blocks at least a shortest path between the transfer channel and the ground region.

12. The image sensor manufacturing method according to claim 11, comprising:
forming a trench having a frame shape that surrounds the transfer channel; and
forming a gate insulation film at least at a side surface of the trench, wherein
the transfer channel is enclosed in a tubular manner by the gate insulation film.

13. The image sensor manufacturing method according to claim 12, comprising:
forming the gate insulation film at a bottom surface of the trench in addition to at the side surface; and
forming a transfer gate on top of the gate insulation film, wherein
a depth of the trench exceeds a thickness of the transfer gate, and
the transfer gate is formed at a bottom part of the trench.

14. The image sensor manufacturing method according to claim 13, comprising
forming the floating diffusion by epitaxial growth.

15. The image sensor manufacturing method according to claim 11, wherein
the transfer channel has a lower impurity concentration than the floating diffusion and the photodiode.

16. The image sensor manufacturing method according to claim 13, comprising
forming the floating diffusion as an embedded layer by ion implantation, wherein
a region of the transfer gate that is relatively close to the floating diffusion has a smaller layer thickness than a region of the transfer gate that is relatively far from the floating diffusion.

17. The image sensor manufacturing method according to claim 13, comprising:
forming the floating diffusion as an embedded layer by ion implantation; and
forming a contact hole which extends deeper than the floating diffusion and reaches the transfer gate.

18. The image sensor manufacturing method according to claim 11, further comprising:
forming a transfer gate adjacent to the transfer channel in a surface direction; and
forming an element-isolating insulation film that surrounds the photodiode, the transfer channel, the floating diffusion, and the transfer gate, wherein
an entire periphery of the transfer channel is enclosed by the gate insulation film and the element-isolating insulation film.

19. The image sensor manufacturing method according to claim 18, comprising:
forming a photoelectric conversion unit including the photodiode, the transfer gate, the gate insulation film, and the element-isolating insulation film; and
further forming a plurality of such photoelectric conversion units, and a single such transfer channel and a single such floating diffusion which are surrounded by the plurality of photoelectric conversion units.

20. The image sensor manufacturing method according to claim 14, comprising
forming the ground region by epitaxial growth.
